(19) United States
(12) Patent Application Publication
(10) Pub. No.: US 2008/0099852 A1
(43) Pub. Date: May 1, 2008

(54) Integrated semiconductor device and method of manufacturing an integrated semiconductor device

(76) Inventor: Juergen Faul, Radebeul (DE)

Correspondence Address: SLATER & MATSIL LLP, 17950 PRESTON ROAD, SUITE 1000, DALLAS, TX, 75252, US

(21) Appl. No.: 11/590,665

(22) Filed: Oct. 31, 2006

(51) Int. Cl. H01L 29/772; H01L 21/336

(52) U.S. Cl. 257/382; 257/408; 438/682; 438/307

(57) ABSTRACT

An integrated semiconductor device includes at least one transistor. A first and a second source/drain diffusion region are arranged in a doped well. A contact structure is arranged on or above the substrate surface and abuts the lateral sidewall of a gate electrode isolation and electrically contacts the first source/drain diffusion region. The first source/drain diffusion region includes a highly doped main dopant region and a further dopant region, both formed of dopants of the same dopant type and spatially overlapping one another. The further dopant region extends deeper into the substrate below the substrate surface than the main dopant region.

### TECHNICAL FIELD

The invention relates to the field of integrated semiconductor devices and their manufacture. Specific embodiments of the invention refer to the field of the design of transistors, such as MOSFETs (metal oxide semiconductor field effect transistors).

### BACKGROUND

In the field of integrated semiconductor devices and their manufacture, integrated circuits are formed on substrates, the integrated circuits comprising a plurality of switching elements like transistors. The integrated transistors often are field effect transistors like metal oxide semiconductor field effect transistors and may be particularly formed as planar transistors with both source/drain regions being arranged at different lateral positions of the substrate surface.

Usually, prior to forming the transistors, doped wells are formed in the substrate in order to provide doped substrate areas for NMOS transistors or pMOS transistors or, combinedly, for forming a CMOS circuit comprising NMOS transistors and pMOS transistors in doped wells of opposite dopant type. Each kind of transistor is to be arranged in a doped well of opposite dopant types, which is one of n-dopant type (e.g., As or P) and p-dopant type (e.g., B).

The source/drain electrodes of a MOSFET transistor usually are formed of dopant diffusion regions comprising dopants that have been implanted or otherwise introduced into the substrate. Usually, the dopants are implanted through the substrate surface to a depth corresponding to a maximum implantation energy of the dopants. A subsequent thermal treatment may be performed subsequently in order to diffuse the dopants within the substrate in a controlled manner. In either case, a dopant diffusion region is formed. Source/drain electrodes comprise a highly doped main dopant implant region with a dopant concentration in the order of between 10¹⁸ and 10²¹ dopant atoms per cm³. Of course, depending on the progress in miniaturization and the improvement in transistor performance, the typical range of source/drain dopant concentrations may shift with the change to future technologies. However, typically the highest dopant concentration of a transistor (considered in the substrate region comprising the transistor) is obtained in the source/drain diffusion regions.

Usually, the source/drain diffusion regions comprise two or more dopant implant regions overlapping one another, each dopant implant region being implanted separately. The plural implantation steps serve to shape more complex dopant concentration profiles within the substrate, in particular in a direction of increasing depth (vertical to the substrate surface) and, furthermore, in a direction parallel to the substrate surface (along the direction x of increasing distance from the channel region of the transistor). For instance, extension regions like LDD regions (lightly doped drain regions) may be provided at a distance range between the channel region and the respective source/drain diffusion region (or its main dopant implant region) in order to reduce the magnitude of electric fields occurring between both source/drain regions on opposite sides of the channel region. In particular, transistors operated at higher voltages include at least one extension region of large lateral dimensions. However, also transistors in a memory array, like selection transistors of memory cells, often comprise LDD regions between the channel region and both source/drain regions. However, with increasing demands on miniaturization, one way of reducing the width of a transistor and the substrate area required per transistor is to omit the LDD regions and to arrange the main dopant implant regions (which in this application are identifying the essential, highly doped implant region of any source/drain diffusion region) more closely to the channel region. In this case, high attention is required in order not to impair the short channel characteristics or other characteristics of the transistor. The source/drain diffusion regions (also called junctions) being formed without any LDD region or extension region are called ‘hard junctions’. In case of a hard junction, only a reduced thermal budget may be applied in order to prevent detrimental influences on transistor performance.

Whereas extension regions typically are used for reducing the lateral slope of the dopant concentration along lateral directions, further efforts serve to influence the dopant concentration profile in a direction perpendicular to the substrate surface, that is in a direction of increasing substrate depth. In particular, since the source/drain regions to be contacted from the substrate surface often are contacted by a Schottky contact, Schottky resistances shall be reduced. In particular, those source/drain electrodes to be connected to a bitline (via a bitline contact) must be contacted with low resistances along the conducting path. It is, therefore, known to provide shallow contact implant dopants into the substrate, thereby forming a shallow contact implant region having a depth in the substrate being smaller than the depth of the main dopant implant region. Thereby, the total dopant concentration close to a substrate surface is increased. Additionally, a silicide layer may be formed on the exposed substrate surface in order to reduce Schottky contact resistances.

Due to the additional implant of the shallow contact implant region, the dopant concentration close to the substrate surface is rather high. The dopant particles (the implanted dopant atoms) cause defects in the monocrystalline crystal lattice of the semiconductor substrate. Thereby, the substrate may be locally converted into amorphous substrate material in regions close to the exposed substrate surface through which the dopants are implanted. This effect of amorphization which strongly reduces electrical conductivity can be compensated by a subsequent thermal anneal step that recrystallizes the substrate material at and close to the exposed substrate surface. However, some defects in the crystal lattice may still be maintained.

Such defects contribute to leakage currents between the respective source/drain diffusion region and the substrate (that is the doped well comprised in the substrate and embedding the transistor). In particular, due to the highly doped main dopant implant region essentially constituting the respective source/drain electrode and extending deeper into the substrate than the shallow contact implant region, a parasitic pn-junction or pn-diode occurs in the substrate. Leakage currents caused by such pn-junctions particularly affect the performance of reading out stored digital information in memory cells comprising a selection transistor. Accordingly, in particular in case of selection transistors, parasitic pn-junctions and leakage currents caused thereby must be minimized.

A known measure for generating steep and ultra-shallow source/drain-profiles (junction profiles) is to co-implant carbon or fluorine atoms into the substrate. However, these co-implants may further generate defects in the crystal lattice or may attract defects already present, which are then maintained even upon performance of an annealing step.

Due to these defects and the parasitic pn-junctions in the substrate, in particular in case of hard junction transistors, the desired properties and performance of the transistor may degrade drastically. For instance, large junction-to-substrate-capacitances (that is source/drain diffusion region-to-substrate capacitances) occur and the desired breakdown voltages and short channel behavior may become worse. Thus, there is a need to provide an improved semiconductor device with reduced leakage currents between source/drain electrodes of transistors and the embedding substrate. There also is a need for providing improved processes for fabricating semiconductor devices.

### SUMMARY OF THE INVENTION

In one embodiment, an integrated semiconductor device comprising at least one transistor, at least one contact structure and a substrate is provided. The substrate includes a planar substrate surface and a doped well arranged in the substrate below the planar substrate surface. The doped well includes dopants of a first dopant type which is one of a p-dopant type and an n-dopant type. The transistor includes a first and a second source/drain diffusion region arranged in the doped well and a channel region. A gate dielectric is arranged on the substrate. A gate electrode structure protrudes above the substrate surface and above the gate dielectric, the gate electrode structure comprising a gate electrode and a gate electrode isolation comprising a lateral sidewall. The contact structure is arranged on or above the substrate surface and is abutting the lateral sidewall of the gate electrode isolation and is electrically contacting the first source/drain diffusion region. The first source/drain diffusion region comprises a highly doped main dopant implant region and a further dopant implant region both formed of dopants of a second dopant type other than the first dopant type and spatially overlapping one another and the further dopant implant region extends deeper into the substrate below the substrate surface than the main dopant implant region.

In another embodiment, an integrated semiconductor device is provided comprising a substrate having a planar substrate surface with at least one recess formed therein. A doped well is arranged in the substrate below the planar substrate surface and the recess, the doped well being formed of dopants of a first dopant type which is one of a p-dopant type and an n-dopant type. At least one contact structure is provided. A transistor is arranged at the recess. The transistor includes a first and a second source/drain diffusion region and a channel region all arranged in the doped well. A gate dielectric is arranged on the substrate and covers sidewalls a bottom surface of the recess. A gate electrode structure is provided on the gate dielectric and fills the recess, the gate electrode structure protruding above the substrate surface outside the recess and comprising a gate electrode and a gate electrode isolation with a lateral sidewall. The contact structure is arranged on or above the substrate surface and is abutting the lateral sidewall of the gate electrode isolation and is electrically contacting the first source/drain diffusion region. The first source/drain diffusion region comprises a highly doped main dopant implant region and a further dopant implant region both formed of dopants of a second dopant type other than the first dopant type and spatially overlapping one another and the further dopant implant region extends deeper into the substrate below the substrate surface than the main dopant implant region.

In another embodiment, an integrated semiconductor device is provided comprising at least one transistor, at least one contact structure and a substrate comprising a planar substrate surface and a doped well arranged in the substrate below the planar substrate surface, the doped well comprising dopants of a first dopant type which is one of a p-dopant type and an n-dopant type. The transistor includes a first and a second source/drain diffusion region arranged in the doped well and a channel region. A gate dielectric is arranged on the substrate. A gate electrode structure protrudes above the substrate surface and above the gate dielectric, the gate electrode structure comprising a gate electrode and a gate electrode isolation comprising a spacer having a lateral sidewall. The contact structure is arranged on or above the substrate surface and is abutting the lateral sidewall of the spacer and is electrically contacting the first source/drain diffusion region. The first source/drain diffusion region comprises a highly doped main dopant implant region and a further dopant implant region both formed of dopants of a second dopant type other than the first dopant type and spatially overlapping one another. The further dopant implant region extends deeper into the substrate below the substrate surface than the main dopant implant region and the lateral position of both the highly doped main dopant implant region and the further dopant implant region is defined by a self-aligned contact hole filled with the contact structure and abutting the lateral sidewall of the spacer.

In another embodiment, a method of manufacturing an integrated semiconductor device comprising at least one transistor is provided. A gate dielectric is formed on a substrate comprising a substrate surface. At least one gate electrode is formed on the gate dielectric. Highly doped main dopant implant regions are formed for a first and a second source/drain diffusion region in the substrate on opposed sides of the gate electrode. Sidewall spacers are formed on gate sidewalls of the gate electrode to form an isolated gate electrode structure comprising lateral sidewalls. Further dopant implant regions are formed for the first and the second source/drain diffusion region in the substrate on opposed sites of the gate electrode structure outside the lateral sidewalls. A contact structure is formed contacting the first source/drain diffusion region, the contact structure abutting the gate electrode structure in self-aligned manner, wherein the further dopant implant regions are formed of a same dopant type which is one of a p-dopant type and an n-dopant type, the further dopant implant regions being formed of dopants of less dopant concentration than a dopant concentration of the main dopant implant regions.

In another embodiment, a method of manufacturing an integrated semiconductor device comprising at least one transistor is provided. A gate dielectric is formed on a substrate comprising a substrate surface. At least one gate electrode is formed on the gate dielectric. Sidewall spacers are formed on gate sidewalls of the gate electrode to form an isolated gate electrode structure, the sidewall spacers each comprising a lateral sidewall. A dielectric layer is deposited on the substrate and at least one self-aligned contact hole is etched into the dielectric layer selectively to a respective sidewall spacer. The at least one contact hole exposes the lateral sidewall of the respective sidewall spacer and further exposes a substrate surface portion confined by the respective sidewall spacer. A highly doped main dopant implant region and a further dopant implant region are implanted through the at least one contact hole for at least one of the first source/drain diffusion region and the second source/drain diffusion region into the substrate outside the lateral sidewall of the at least one spacer exposed. At least one contact structure is formed contacting one of the source/drain diffusion regions, the at least one contact structure abutting the lateral sidewall of the respective spacer, wherein each further dopant implant region is formed of a same dopant type which is one of a p-dopant type and an n-dopant type, the further dopant implant region being formed of dopants of less dopant concentration than a dopant concentration of the respective main dopant implant region.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates an integrated semiconductor device according to a first embodiment of the invention;

FIG. 2 illustrates an integrated semiconductor device according to a second embodiment of the invention;

FIG. 3 schematically illustrates a vertical dopant concentration profile of a source/drain diffusion region according to an embodiment of the invention;

FIG. 4 schematically illustrates a lateral dopant concentration profile according to an embodiment of the invention;

FIG. 5, in more detail, illustrates the vertical dopant concentration profile of FIG. 3;

FIG. 6 illustrates an integrated semiconductor device comprising at least one transistor formed according to the invention; and

FIGS. 7 and 8 illustrate method steps of an embodiment of a method according to the invention.

The following list of reference symbols can be used in conjunction with the figures:

| | |
|---|---|
| 1 | semiconductor device |
| 2 | substrate |
| 2a | substrate surface |
| 2b | substrate surface portion |
| 3 | doped well |
| 4 | channel region |
| 5 | gate dielectric |
| 6 | gate electrode structure |
| 7 | gate electrode |
| 7a | gate sidewall |
| 8 | gate electrode isolation |
| 8a | lateral sidewall |
| 9 | sidewall spacer |
| 10 | transistor |
| 11 | main dopant implant region |
| 12 | further dopant implant region |
| 13 | shallow contact implant region |
| 14 | extension region |
| 15 | first source/drain diffusion region |
| 16 | second source/drain diffusion region |
| 20 | contact structure |
| 21 | conductive contact layer |
| 21a | contact hole |
| 22 | bitline |
| 23 | storage capacitor |
| 24 | memory cell |
| 25 | memory array |
| 26 | dielectric layer |
| 27 | periphery region |
| 40 | mobile electronic device |
| B | bottom surface |
| C | dopant concentration |
| C″ | second derivative of dopant concentration |
| | to depth |
| | c; c3, c11, . . . concentration |
| | d; d11, d12, . . . depth |
| M | maximum |
| n; p | dopant type |
| P | dopant concentration profile |
| R | recess |
| R1 | first range of depth |
| R2 | second range of depth |
| S | sidewall |
| X | first lateral direction |
| Z | vertical direction |

### DETAILED DESCRIPTION OF ILLUSTRATIVE EMBODIMENTS

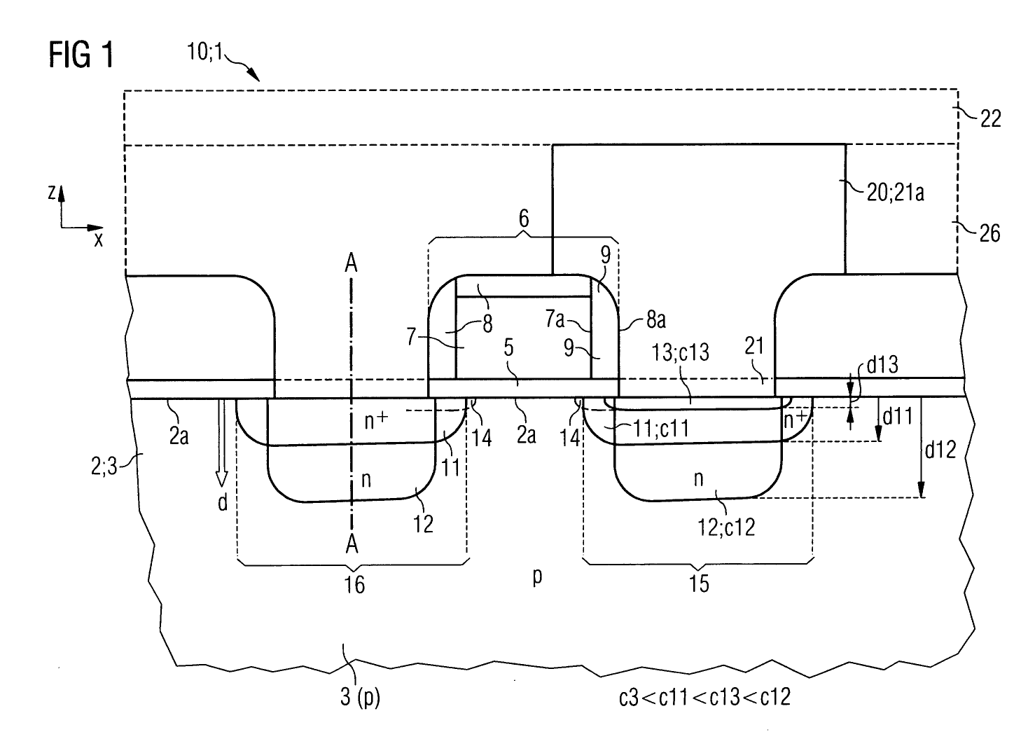

FIG. 1 illustrates a semiconductor device according to a first embodiment of the invention. The integrated semiconductor device 1 comprises a substrate 2 having a planar substrate surface 2a and a doped well 3 arranged in the substrate 2. Of course, the substrate can be a doped substrate, the doped well 3 either corresponding to the complete substrate volume of the substrate 2 or, alternatively, only extending in a portion of the substrate volume. Preferably, the doped well 3 is a well that only extends in a portion of the substrate 2. The doped well 3 is formed of dopants, which are one of n-dopants and of p-dopants. A transistor 10 is formed in the doped well 3, the transistor comprising a first source/drain diffusion region 15 and a second source/drain diffusion region 16 both arranged in the doped well 3 and defining (and being provided on opposed sides of) a channel region 4 arranged. On the substrate surface 2a, a dielectric layer is provided, the dielectric layer including a gate dielectric 5. A gate electrode structure 6 is arranged on the dielectric layer, the gate electrode structure 6 thereby defining the portion of the dielectric layer serving as a gate dielectric 5. The gate electrode structure 6 comprises a conductive gate electrode 7, which may comprise one or more gate electrode layers stacked on one another. The gate electrode structure 6 further comprises a gate electrode isolation 8 isolating sidewalls 7a of the gate electrode 7 and isolating an upper surface of the gate electrode 7. Accordingly, the gate electrode is encapsulated by the gate electrode isolation 8. The gate electrode isolation 8 in particular isolates the gate electrode 7 in a lateral direction and comprises lateral sidewalls 8a forming part of the gate electrode isolation. Preferably, the gate electrode isolation 8 comprises sidewall spacers 9 provided on each of two opposed sidewalls 7a of the gate electrode 7. Accordingly, on opposed sides of the gate electrode structure 6, the respective lateral sidewall 8a forms a sidewall of the respective sidewall spacer 9. Below the gate electrode structure 6, the substrate area covered with the gate electrode 7 constitutes the channel region 4, which is arranged between the first and the second source/drain diffusion region 15, 16.

The first source/drain diffusion region 15 is arranged, in positive first direction x, beside the channel region 4. The first source/drain diffusion region 15, according to embodiments of the invention, includes a dopant concentration profile formed of at least two different dopant implant regions 11, 12 overlapping one another. Both dopant implant regions have been implanted (or otherwise introduced in the substrate) separately (with different process steps or a combined process step), for instance by way of implantation. Accordingly, both dopant implant regions comprise different spatial extensions, different dopant concentrations and/or different dopant species. However, the dopant species of both dopant implant regions are of the same dopant type (that is both n-dopant type or both p-dopant type).

The first dopant implant region of the first source/drain diffusion region 15 is a main dopant implant region 11 essentially constituting a first source/drain electrode of the transistor. The second dopant implant region is a further dopant implant region 12 extending to a larger depth d12 compared to the depth d11 of the main dopant implant region 11 of the first source/drain diffusion region 15. The further dopant implant region 12 comprises a dopant concentration c12 less than the dopant concentration c11 of the main dopant implant region 11. Preferably, the further dopant implant region 12 further is arranged at a slightly larger distance in a lateral direction x from the channel region 4, wherein the lateral offset between the further dopant implant region 12 compared to the main dopant implant region 11, at the lateral side facing the channel region 4, preferably may correspond to the lateral thickness of the spacer 9.

It is to be noted that the spacer 9 may be formed of a set of two or more spacers, like an inner spacer arranged closer to the gate electrode 7 and an outer spacer arranged on the inner spacer and comprising the lateral sidewall 8a of the gate electrode structure 6. However, the lateral dimension of the gate electrode structure 6, when implanting the dopants for the further dopant implant region 12, shall be larger than the lateral dimension of the gate electrode 7 (or of the non-completed gate electrode structure) as present when implanting the dopants for the main dopant implant region 1.

The dopant concentration profile of the first source/drain diffusion region 15 (and, preferably, also of the second source/drain diffusion region 16) thus is constituted at least by a main dopant implant region 11 and a deeper, less concentrated further dopant implant region 12. The dopant concentration obtained by the further dopant implant region 12 may be smaller, by a factor of between about 10 and about 100, compared to the dopant concentration of the main dopant implant region 11. In FIG. 1, the dopant type of both dopant implant regions 11, 12 is ‘n’ and, consequently, the doped well 3 is formed of a p-dopant. Since the dopant type of the first (and second) source/drain diffusion region is different from the dopant type of the doped well, a parasitic pn-junction is formed therebetween, leakage currents being enabled to pass the pn-junction even if operated in reverse mode. The leakage currents result from defects in the crystal lattice, from co-implants (of carbon or fluorine, for instance) present in the substrate and/or from other parasitic effects. These effects may, for instance, result from undesired local amorphization and subsequent intentional recrystallization of the source/drain regions close to the substrate surface where the dopants are implanted through the substrate surface.

In particular, in case of a third dopant implant region 13 serving as a shallow contact implant region close to the substrate surface 2a, in the region of a self-aligned contact hole or another contact region adjacent to the substrate area covered with the gate electrode structure 6, high amounts of dopants are implanted through and maintained in the area of the first (and second) source/drain diffusion region directly below the substrate surface 2a. In this case, the crystal lattice damages to be annealed thermally are significant.

The shallow contact implant region 13 extends to a smaller depth d13 compared to the main dopant implant region 11 but may have a dopant concentration c13 larger than the dopant concentration c12 of the further, deepest dopant implant region 12.

In both cases, in the absence as well as in the presence of the additional shallow contact implant region 13, a comparatively large dopant concentration c11 (of, for instance, between about 10¹⁸ and about 10²¹ dopant atoms per cm³), the pn-junction between the bottom region of the main dopant implant region 11 and the doped well 3 is comparatively close to the highly conductive main dopant implant region 11. Accordingly, the pn-junction is rather close to highly doped substrate areas of the first source/drain diffusion region. At the same time, defects in the crystal lattice and/or co-implants may contribute to parasitic currents through the reverse biased pn-junction.

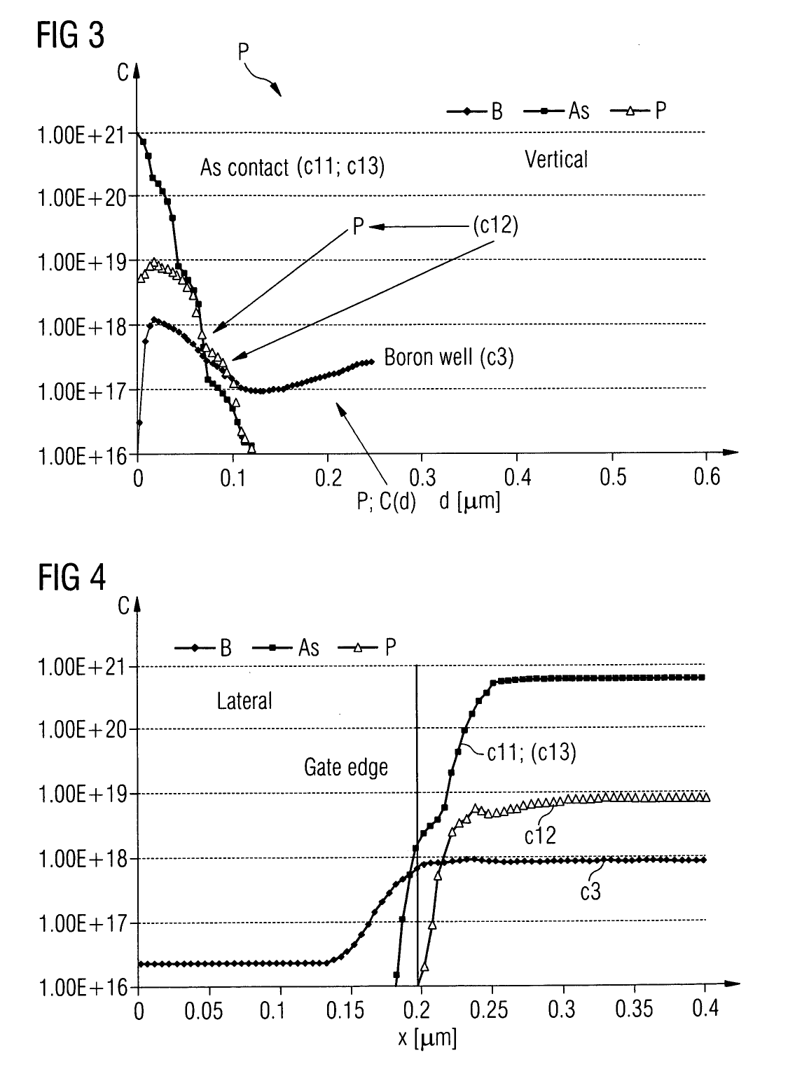

According to embodiments of the invention, however, the further dopant implant region 12 extends to a larger depth than the main dopant implant region 11 but comprises a lower dopant concentration than the main dopant implant region 1, thereby extending the source/drain diffusion region deeper into the substrate and thus increasing the distance between the parasitic pn-junctions and the substrate surface. In particular, regarding the dopant concentration profile of the first source/drain diffusion region 15 in a vertical direction z of increasing substrate depth d, the presence of the further dopant implant region 12 generates a ‘shoulder’ in the dopant concentration profile in a region of increased substrate depth. This dopant concentration profile P will be explained with reference to FIGS. 3 and 5. However, as already apparent from FIG. 1, the parasitic pn-junction established between the p-doped well 3 and the lowermost portion of the n-doped first source/drain diffusion region 15, as provided according to embodiments of the invention, is arranged deeper within the substrate than in absence of the further dopant implant region.

Furthermore, due to the reduced dopant concentration c 12 of the further dopant implant region compared to the dopant concentration c11 of the main dopant implant region 11, lower electric fields occur within the source/drain diffusion regions 15, 16 and the doped well, in particular in direction of increasing substrate depth d. Accordingly, the amount of leakage currents passing the reverse biased pn-junction is reduced significantly. In particular, in case that the transistor 10 as constructed according to embodiments of the invention is a selection transistor of a memory, the reliability of correctly reading out stored charges from the memory cells is increased significantly due to the reduction of leakage currents.

The semiconductor device according to embodiments of invention may further comprise a contact structure 20 electrically connecting the first source/drain diffusion region 15. The contact structure preferably is abutting the substrate surface 2a or an upper surface of a conductive contact layer 21, like the silicide layer, arranged on the substrate surface 2a. The contact structure 20 according to the embodiment of FIG. 1 preferably is a self-aligned contact structure, which is abutting at least the lateral sidewall 8a of the gate electrode isolation 8 of the gate electrode structure 6. Furthermore, also the opposed lateral side of the contact structure 20 may abut a further isolating structure illustrated at the right side of the contact structure 20 in FIG. 1. Accordingly, the contact structure 20 preferably is a self-aligned plug or via filling structure, which has a lateral dimension larger than the recess formed between two opposed isolating structures (like the gate electrode isolation 8 and an isolating structure of a further structure, like another wordline, for instance). Accordingly, the lateral extension of the contact structure 20 is larger than the cross-section compared to the substrate surface (or of the silicide layer surface) exposed between these isolating structures laterally confining the shape of the bottom portion of the contact structure. In particular, due to the self-aligned embodiment of the contact structure 20, the bottom portion of the contact structure 20 has a smaller lateral extension, along one or two lateral directions, than an upper portion of the contact structure 20. In particular, the lateral dimensions of the bottom portion of the contact structure 20 may be smaller than a critical dimension used for designing the smallest lateral distances lithographically patterned on the integrated semiconductor device.

The transistor 10 usually further comprises a second source/drain diffusion region 16. Preferably, the second source/drain diffusion region 16, like the first source/drain diffusion region 15, comprises a further dopant implant region 12 in addition to the main dopant implant region 11, in particular in case that the transistor 10 is formed in a periphery region or another kind of logic region or in a memory array region. Finally, also the second source/drain diffusion region 16 may further comprise, like the first source/drain diffusion region 15, a shallow contact implant region 13. However, irrespective of whether the transistor 10 is formed in a memory cell array of the semiconductor device or in another region, like a logic region or periphery region thereof, only one contact structure 20 needs to be present on the exposed surfaces, for instance on the surface of the first or second source/drain diffusion region 15 or 16.

In case that the transistor 10 is a selection transistor of a memory cell comprised in a memory array of the semiconductor device 1, the second source/drain diffusion region 16 may be electrically connected to a storage capacitor, which preferably is one of a deep trench capacitor formed in the substrate 2 or a stacked capacitor (preferably formed on or above the substrate).

The further dopant implant region 12 provided according to embodiments of the invention preferably is implanted by implanting dopants of an implant dose of between about 4*10¹² and about 4*10¹⁴ particles per cm², for instance about 4*10¹³ atoms/cm², in particular in case that phosphorous is implanted. The dopants of the further dopant implant region may be implanted, for instance, with an implantation energy of between about 5 and about 15 kV, for instance between about 8 and about 12 kV. These ranges of implant dose and of implantation energy may apply to implants of phosphorous P, for instance. Of course, other numerical ranges may be used in case of other dopant species than phosphorous. The further dopant implant region may be formed of dopants like B or, in case of n-dopants, As or P, for instance. The further dopant implant region 12 serves to reduce leakage current from the respective source/drain diffusion region to the substrate (that is to the doped well 3 in the substrate 2).

Furthermore, an additional shallow contact implant region 13 may be implanted into the substrate, for instance by implanting an implant dose of between about 10¹⁴ and about 10¹⁶ atoms/cm², for instance about 10¹⁵ atoms/cm². The implantation energy may be chosen between about 8 and about 12 kV, for instance. For instance, As atoms may be implanted with an energy of about 10 kV.

Preferably, the further dopant implant region 12 (and, if present, also the shallow contact implant region 13) are implanted into the substrate through a self-aligned contact hole which is represented in FIG. 1 above the lateral extension of the silicide layer 21, or, respectively, by the exposed substrate surface portion at the bottom of the silicide layer 21 at the stage of the manufacturing process when the contact structure 20 is not yet formed thereon. Accordingly, due to the sidewall spacer 9 formed after implantation of a main dopant implant region 11, the further dopant implant region 12 comprises a lateral offset (caused by the spacer 9) since the further dopant implant region 12 is formed after formation of the spacers 9 at the wordlines or gate electrode structures 6. After the further dopant implant region 12 has been implanted through the exposed substrate portions between the gate electrode structures 6, the contact structure 20 is formed, preferably in a self-aligned manner, for instance by depositing a dielectric layer, which planarizes the substrate by etching a contact hole laterally broader than the substrate surface portion corresponding to the lateral dimension of the silicide layer 21, and by filling the contact hole or via with a plug or contact hole filling structure, which then forms the contact structure 20. The contact structure 20 preferably is a bitline contact connecting the transistor to a bitline subsequently formed on the dielectric layer planarizing the substrate surface. As illustrated in FIG. 1, the contact structure 20 preferably is a borderless contact structure partially overlapping in lateral direction with at least one gate electrode structure 6.

Finally, optional extension regions 14 (LDD regions) formed by extension dopant implantation are indicated by dashed lines in FIG. 1. They are formed of the same dopant type as the main dopant implant regions 11. Furthermore, pocket regions or halo regions of a different dopant type may be provided in addition.

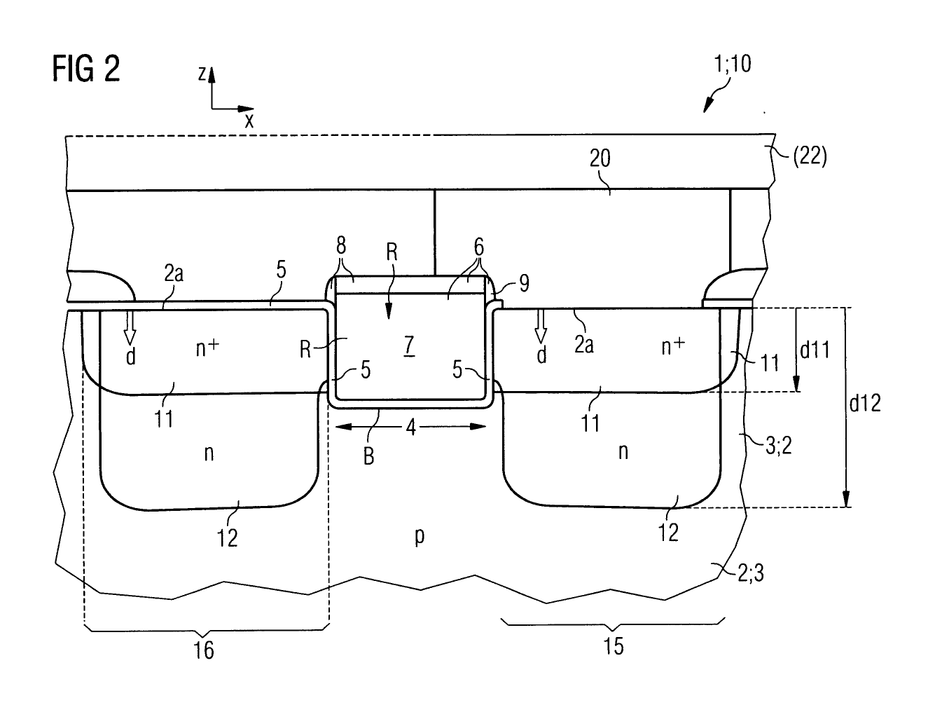

FIG. 2 illustrates a further embodiment of a semiconductor device 1 according to embodiments of the invention. According to FIG. 2, the substrate 2 comprises a recess R in the substrate surface 2a, the recess comprising a bottom surface B and lateral sidewalls S all covered with the gate dielectric 5. Accordingly, the gate electrode 7 is filling the recess R and thus is arranged deeper compared to FIG. 1. Furthermore, in FIG. 2, the first and the second source/drain diffusion regions 15, 16 only comprise the main dopant implant region 111 and the further dopant implant region 12 of same dopant type, but extending deeper into the substrate and comprising a lower dopant concentration compared to the main dopant implant region 11. Of course, the embodiments regarding presence/absence of the additional shallow contact implant region 13 and the presence/absence of a recess in FIGS. 1 and 2 can be mixed with one another. Furthermore, these embodiments may further be combined with regard to further embodiments of other figures, claims or passages of the present application. For instance, in FIG. 2, no silicide layer is disposed between the substrate surface 2a and the contact structure 20. The contact structure 20 need not necessarily be a bitline contact. Instead, any other conductive structure other than a bitline 22 may be connected to the first source/drain diffusion region 15 by the contact structure 20.

In FIG. 2, the channel region 4 of the transistor 10 extends below the bottom surface B of the recess R. Furthermore, the lateral sidewalls S of the recess preferably may define the lateral extension of at least the main dopant implant region 11 at the lateral side facing the recess R and the channel region 4. The lateral extension of the further dopant implant region 12 at the lateral direction facing the channel region and the recess may be defined by the lateral sidewalls S of the recess R or by the spacers 9 or may combinedly be defined by both of them. For instance, according to FIG. 2, the lateral dimension of the further dopant implant region 12 close to the recess is defined, in an upper portion, by the lateral sidewalls S of the recess whereas in a larger depth in the substrate, its lateral dimension is defined by the spacer 9. Of course, the dopant profile and dimensions in FIGS. 1 and 2 are only schematical for the purpose of illustrating exemplary embodiments of the invention.

Finally, as in FIG. 1, FIG. 2 further illustrates a dielectric layer in which the contact structure 20 is arranged as a contact hole filling abutting the gate electrode structure in a self-aligned manner.

FIG. 3 schematically illustrates an exemplary dopant concentration profile P according to one embodiment of the invention. FIG. 3 illustrates the concentration of the vertical concentration profile of dopants as indicated by the dashed line AA in FIG. 1, for the second source/drain diffusion region 16 or, more preferably, at a corresponding position through the first source/drain diffusion region 15. As illustrated in FIG. 3, the vertical dopant concentrations C in dependence of the substrate depth d are illustrated for different dopant implantation regions. For instance, the background dopant profile of the doped well 3 is indicated, which, according to FIG. 3, may be, for instance, a concentration c3 of boron B implanted in the substrate. Furthermore, the main dopant implant region 11 and, if present, also the shallow contact implant region 13 may be formed of As dopants, which combinedly result in a rather shallow, but highly concentrated dopant implant region of As. As further illustrated in FIG. 3, according to embodiments of the invention, additionally a further dopant implant region is formed, for instance of phosphorous implant dopants P at a concentration c12 (marked by triangular dopant concentration measurement points indicated in FIG. 3), which lead to a ‘shoulder’ in the all n-dopants (As and P) constituting the dopant concentration C or the dopant concentration profile P of the first (or second, respectively) source/drain diffusion region 15, 16. Accordingly, the total n-dopant concentration is extending deeper into the substrate, thereby reducing leakage currents to the substrate well. The dopant concentration C of the dopant concentration profile P will be explained in further detail with reference to FIG. 5.

FIG. 4 illustrates an exemplary embodiment regarding the lateral dopant concentration that might be read in combination with FIG. 3 but does not necessarily need to be taken in combination with FIG. 3. According to FIG. 4, the dopant concentration in close distance from the substrate surface is illustrated. At a gate edge indicated in FIG. 4, a dopant concentration of As due to the main dopant concentration c11 (and, if present, also of the shallow contact implant region) is illustrated. Furthermore, an additional implant dose of the further dopant implant region 12 (made of phosphor in FIG. 4) is illustrated. As apparent from the vertical phosphor dopant profile in FIG. 3, the phosphor implant increases the total n-dopant concentration in particular in a substrate depth of between about 0.08 and about 0.11 μm. Of course, other dopants may be chosen for forming the further dopant implant region 12.

FIG. 5, in more detail, illustrates the vertical dopant concentration C of a source/drain diffusion region 15, 16 according to an embodiment of the present invention. In FIG. 5, the dopant concentration C of source/drain dopant particles (for instance, n-dopant particles in the example of FIGS. 1 to 4) is illustrated in dependence of the depth d in the substrate 2. As apparent from FIG. 5, a total concentration of source/drain dopant particles is indicated by a continuous line whereas the dopant concentration c11 of the main dopant implant region 11 as well as the dopant concentration c12 of the further dopant implant region 12 are indicated by dashed lines in FIG. 5. As apparent from FIG. 5, the maximum M of the dopant concentration is positioned comparatively close to the substrate surface (depth d=0 in the substrate). However, in addition a ‘shoulder’ of increased dopant concentration is obtained in a larger depth due to the presence of a further dopant implant region 12 with dopant concentration c12. In particular, the further dopant implant region 12 leads to a first range R1 deeper in the substrate in which first range R1 the second derivative C″ of the dopant concentration C, derivated to the depth d in the substrate, is negative rather than positive. Furthermore, in a second range of depth R2, closer to the substrate surface but deeper in the substrate compared to the maximum dopant concentration M, the second derivative C″ of the dopant concentration to the substrate depth d is positive. Generally, beginning from the substrate surface or from the depth of maximum dopant concentration M, for instance, a first (shallow) range of depth of negative second derivative C″ of the dopant concentration C to the depth, a second (shallow) range of depth R2 of positive second derivative C″ of the dopant concentration C to the depth, a third (deeper) range of depth R1 of negative second derivative C″ of the dopant concentration C to the depth and a fourth (deeper) range of depth of positive second derivative C″ of the dopant concentration C to the depth may follow one another in a direction of increasing substrate depth.

Usually, in absence of the further dopant implant region 12, the second derivative of the dopant concentration C″ would be positive in the complete range from the depth d11 of the main dopant implant region 11 to the back surface of the substrate 2. Instead, the region of positive second derivative C″ is interrupted, in a range of depth R1 approximately corresponding to the depth d12 of the further dopant implant region 12, by a concentration profile region of negative second derivative C″, that is d²C/d(d)², thereby defining a ‘shoulder’ of the vertical source/drain dopant concentration profile.

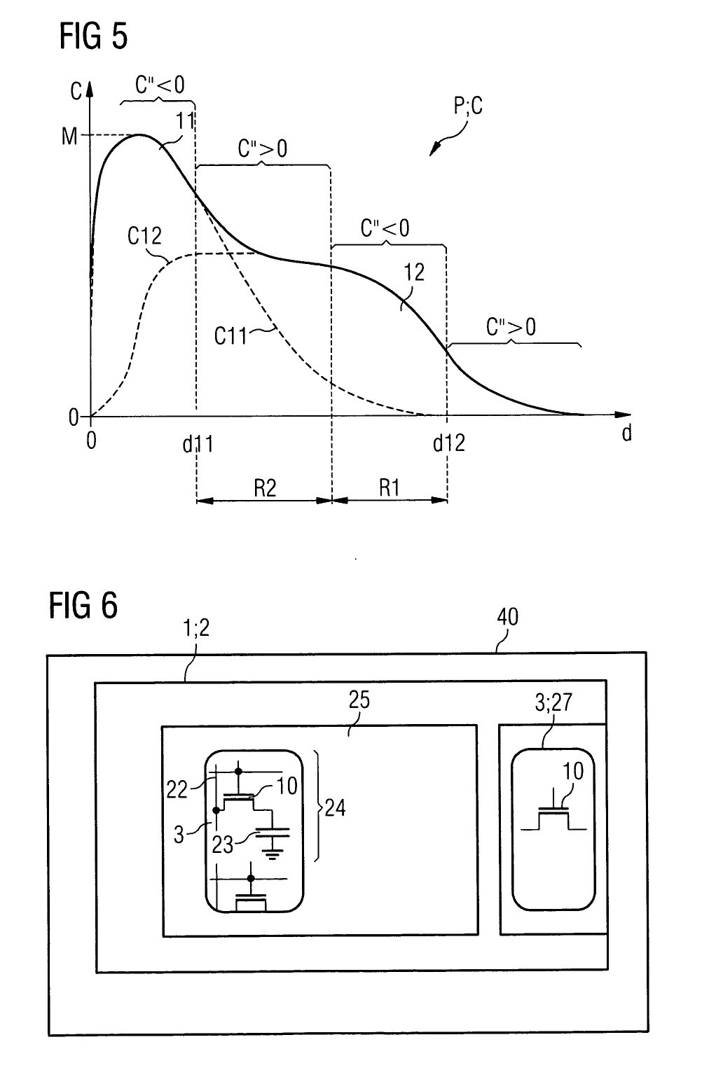

FIG. 6 schematically illustrates an integrated semiconductor device 1 comprising at least one transistor 10 formed according to the invention. The transistor 10 may be provided, alternatively or combinedly, in a memory array 25 and/or a periphery region 27. Although doped wells 3 are illustrated in FIG. 6, the substrate 2 itself may constitute the doped well instead. As further illustrated in FIG. 6, the transistor 10 may form part of a memory cell 24 comprised in a memory array 25 (which comprises a plurality of memory cells 24). In particular, the memory cell comprising the transistor 10 may be connected to a bitline 22 and to a wordline constituting the gate electrode of the transistor. Furthermore, the memory cell 24 may further comprise a storage capacitor 23, like a deep trench capacitor or a stacked capacitor.

The memory array may be a flash memory array, a dynamic random access memory array or any other kind of volatile or non-volatile memory array. The semiconductor device 1 may further be or form part of a mobile electronic device, like a mobile phone, for instance.

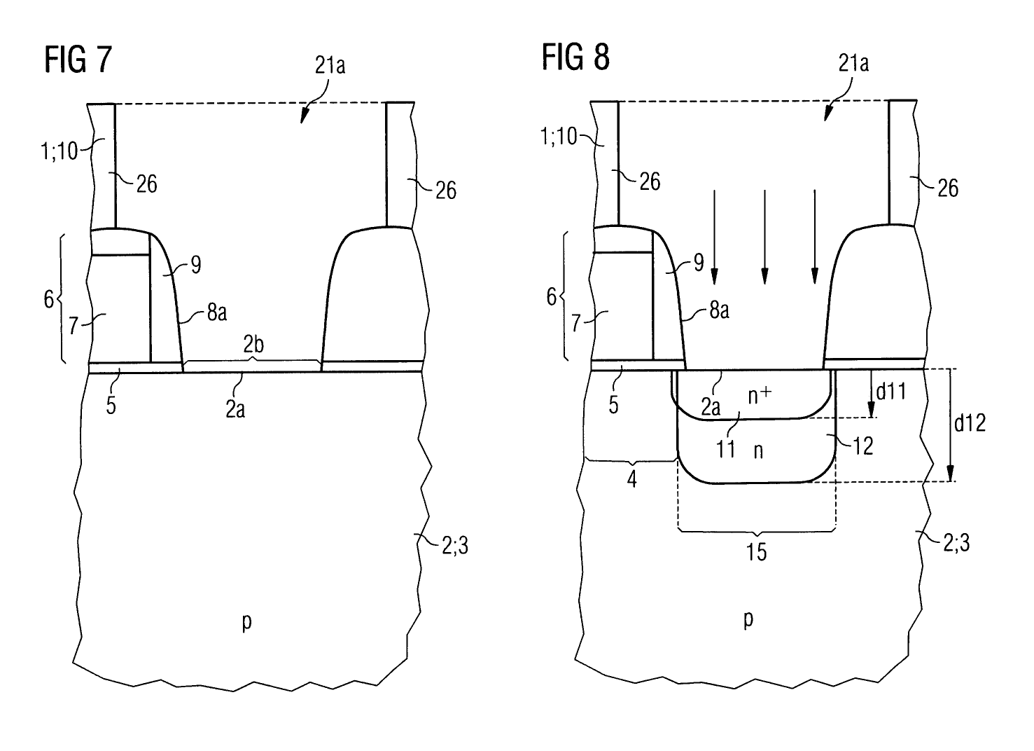

FIGS. 7 and 8 illustrate selected method steps of an embodiment of a method according to the invention.

FIG. 7 illustrates a portion of a semiconductor device during manufacture, the illustrated portion corresponding to the right side of FIG. 1, for instance, and thus showing the portion in which the first source/drain diffusion region 15 is to be formed. However, according to the embodiment of FIG. 7 the main source/drain implant region 11 has not yet been implanted though the spacers 9 already have been formed on the gate sidewalls of the gate electrode 7. Instead, first a dielectric layer 26 which is a planarizing dielectric layer 26 is deposited and patterned, thereby forming at least one contact hole 21a therein. The contact hole 21a is etched selectively to the spacer 9.

One contact hole 21a may be formed in order to electrically contact the first source/drain diffusion region 15. Alternatively, two contact holes 21a may be formed in order to electrically contact the first 15 and the second source/drain diffusion regions 16. Of course, a plurality of further contact holes may be formed at the same time. However, the substrate surface portions 2b for both or, alternatively, for only one of the two source/drain diffusion regions 15, 16 of the transistor 10 may be exposed in order to form the respective source/drain diffusion region 15, 16 therein and in order to electrically contact it/them by a respective contact hole. For instance, if both source/drain diffusion regions 15, 16 are contacted, both contact holes 21a (and thus, also the respective contact structures 20) may be offset relative to one another in direction of the wordline, that is perpendicular to the drawing plane of FIG. 7.

According to FIGS. 7 and 8, the source/drain diffusion regions 15, 16 are implanted through the contact hole(s) 21a into the substrate. Accordingly, they are formed self-aligned to the spacers 9 (rather than self-aligned to the gate electrode sidewalls 7a as in FIG. 1). Accordingly, as illustrated in FIG. 8, the lateral position of the source/drain diffusion regions 15, 16 at the lateral end facing the channel region 4 is defined by the position of the sidewall 8a of the respective lateral spacer 9. According to this embodiment no source/drain implantation step is performed prior to formation of the spacers. Instead, the source/drain diffusion regions 15, 16 including the main dopant implant region 11 are formed after formation of the spacers. Optional shallow contact implant regions 13 or extension regions 14 are not explicitly illustrated in FIG. 8.

Finally, each contact hole 21a in FIG. 8 is filled with a contact structure 20 (with or without a silicide layer provided thereunder). The features of the embodiment of FIGS. 7 and 8, or course, can be combined with those embodiments of the further figures, claims and passages of the specification.

What is claimed is:

1. An integrated semiconductor device comprising at least one transistor, at least one contact structure and a substrate comprising a planar substrate surface and a doped well arranged in the substrate below the planar substrate surface, the doped well comprising dopants of a first dopant type which is one of a p-dopant type and an n-dopant type, the at least one transistor comprising:
a first and a second source/drain region arranged in the doped well and separated by a channel region;
a gate dielectric arranged over the substrate;
a gate electrode structure protruding above the planar substrate surface and above the gate dielectric, the gate electrode structure comprising a gate electrode and a gate electrode isolation comprising a lateral sidewall;
wherein the at least one contact structure is arranged on or above the planar substrate surface and abuts the lateral sidewall of the gate electrode isolation and electrically contacts the first source/drain region;
wherein the first source/drain region comprises a highly doped main dopant region and a further dopant region both formed of dopants of a second dopant type other than the first dopant type and overlapping one another; and
wherein the further dopant region extends deeper into the substrate below the planar substrate surface than the main dopant region.

2. The semiconductor device of claim 1, wherein the first source/drain region and the at least one contact structure are laterally arranged beside the gate electrode structure and the channel region along a first lateral direction and wherein a lateral position of the further dopant implant region along the first lateral direction is defined by the lateral sidewall of the gate electrode isolation.

3. The semiconductor device of claim 1, wherein the main dopant region is located closer, along a first lateral direction, to the channel region compared to the further dopant region.

4. The semiconductor device of claim 1, wherein a lateral position of the main dopant region is defined by a gate sidewall of the gate electrode within the gate electrode structure.

5. The semiconductor device of claim 1, wherein the gate electrode isolation comprises at least one sidewall spacer laterally isolating the gate electrode and comprising the lateral sidewall of the gate electrode structure.

6. The semiconductor device of claim 5, wherein the at least one contact structure physically touches the at least one sidewall spacer of the gate electrode structure.

7. The semiconductor device of claim 1, wherein the at least one contact structure abuts the gate electrode structure in a self-aligned manner.

8. The semiconductor device of claim 1, wherein the main dopant region comprises a first dopant concentration and wherein the further dopant region comprises a second dopant concentration less than the first dopant concentration but larger than a dopant concentration of the doped well.

9. The semiconductor device of claim 8, wherein the first dopant concentration of the main dopant implant region extends closer, along a first lateral direction, to the channel region than the second dopant concentration of the further dopant implant region.

10. The semiconductor device of claim 1, wherein the main dopant region is shallower than the further dopant region.

11. The semiconductor device of claim 1, wherein the overlapping main dopant region and further dopant region of the first source/drain region combinedly define a dopant concentration profile of dopants of the second dopant type provided in the substrate below the at least one contact structure, the dopant concentration profile having a dopant concentration varying with increasing depth in the substrate.

12. The semiconductor device of claim 11, wherein the dopant concentration profile comprises a maximum of dopant concentration due to the main dopant region and wherein a second derivative of the dopant concentration of the dopant concentration profile, derivated to the depth in the substrate, is negative in a first range of depth enclosing or being close to a depth of the further dopant implant region.

13. The semiconductor device of claim 12, wherein the second derivative of the dopant concentration of the dopant concentration profile to the depth is positive in a second range of depth between the first range of depth and a depth of the maximum of dopant concentration.

14. The semiconductor device of claim 1, wherein the further dopant region reduces leakage current between the at least one contact structure and the doped well or the substrate.

15. The semiconductor device of claim 1, wherein the main dopant region and the further dopant region are formed of n-type dopants.

16. The semiconductor device of claim 1, wherein the main dopant region and the further dopant region are formed of dopants of the same species of dopant atoms.

17. The semiconductor device of claim 13, wherein the dopant concentration of the dopant concentration profile of the first source/drain region, in a depth between the first and the second range of depth, is less than the maximum of dopant concentration of the dopant concentration profile, by a factor of between about 10 and about 100.

18. The semiconductor device of claim 13, wherein the dopant concentration of the dopant concentration profile, in a depth between the first and the second range of depth, is between about 10¹³ and about 10¹⁶ dopant atoms per cm³.

19. The semiconductor device of claim 1, further comprising an extension region or lightly doped drain region between the channel region and the main dopant region.

20. The semiconductor device of claim 1, further comprising a conductive contact layer on the planar substrate surface between the first source/drain diffusion region and the at least one contact structure.

21. The semiconductor device of claim 20, wherein the conductive contact layer is formed of a silicide.

22. The semiconductor device of claim 1, wherein the first source/drain region further comprises a shallow contact region of a same dopant type as the main dopant region and the further dopant region and wherein the shallow contact region is provided in the substrate below the at least one contact structure.

23. The semiconductor device of claim 22, wherein the shallow contact region extends into the substrate to a depth less than the depth of the main dopant implant region.

24. The semiconductor device of claim 23, wherein the dopant concentration of the dopant concentration profile of the first source/drain region comprises a maximum close to the planar substrate surface in a depth at which the main dopant region, the further dopant region and the shallow contact region spatially overlap each other.

25. The semiconductor device of claim 1, wherein the at least one transistor is a selection transistor of a memory cell in a memory array disposed in the integrated semiconductor device.

26. The semiconductor device of claim 25, wherein the at least one contact structure is a bitline contact contacting the first source/drain region of the at least one transistor and bitline.

27. The semiconductor device of claim 25, further comprising a storage capacitor connected to the second source/drain region of the at least one transistor.

28. The semiconductor device of claim 1, wherein the at least one transistor is arranged in a peripheral region or in a logic circuit region of the integrated semiconductor device.

29. The semiconductor device of claim 1, wherein the at least one transistor is arranged at a recess in the planar substrate surface, the gate dielectric covering sidewalls and a bottom surface of the recess, and wherein the gate electrode structure fills the recess and protrudes above the planar substrate surface outside the recess.

30. The semiconductor device of claim 29, wherein the sidewalls of the recess laterally confine the main dopant region and the further dopant region arranged outside the recess, the channel region extending below the bottom surface of the recess.

31. The semiconductor device of claim 29, wherein the gate electrode isolation is arranged laterally outside the recess on the planar substrate surface.

32. The semiconductor device of claim 1, wherein the at least one transistor further comprises first and second source/drain electrodes arranged on opposed sides of the gate electrode structure and of the channel region and formed mirror-inverted with respect to one another.

33. The semiconductor device of claim 1, wherein the integrated semiconductor device fills a semiconductor memory.

34. The semiconductor device of claim 1, wherein the integrated semiconductor device is a mobile electronic device.

35. The semiconductor device of claim 1, wherein the first source/drain region and the second source/drain region each comprise a highly doped main dopant region and a further dopant region.

36. An integrated semiconductor device comprising:
a substrate having a planar substrate surface with at least one recess formed therein;
a doped well arranged in the substrate below the planar substrate surface and the recess, the doped well being formed of dopants of a first dopant type, the first dopant type being one of a p-dopant type and an n-dopant type;
a first source/drain region, a second source/drain region and a channel region all arranged in the doped well, wherein the first source/drain region comprises a highly doped main dopant region and a further dopant region both formed of dopants of a second dopant type, the second dopant type being opposite the first dopant type, the main dopant region and the further dopant region spatially overlapping one another, wherein the further dopant region extends deeper into the substrate below the planar substrate surface than the main dopant region;
a gate dielectric covering sidewalls and a bottom surface of the recess;
a gate electrode structure provided on the gate dielectric and filling the recess, the gate electrode structure protruding above the planar substrate surface outside the recess and including a gate electrode and a gate electrode isolation with a lateral sidewall; and
a contact structure arranged on or above the planar substrate surface and abutting the lateral sidewall of the gate electrode isolation, the contact structure electrically contacting the first source/drain region.

37. The semiconductor device of claim 36, wherein the sidewalls of the recess laterally confine the main dopant region and the further dopant region, the channel region extending below the bottom surface of the recess.

38. The semiconductor device of claim 36, wherein the first source/drain region and the contact structure are arranged laterally adjacent to the recess along a first lateral direction.

39. The semiconductor device of claim 36, wherein the further dopant region extends in a direction away from the planar substrate surface deeper into the substrate than the channel region.

40. The semiconductor device of claim 36, wherein the second source/drain region comprises a highly doped main dopant region and a respective further dopant region.

41. A method of manufacturing an integrated semiconductor device comprising at least one transistor, the method comprising:
forming a gate dielectric over a surface of a substrate;
forming a gate electrode over the gate dielectric;
forming highly doped main dopant regions for a first and a second source/drain region in the substrate on opposed sides of the gate electrode;
forming sidewall spacers on gate sidewalls of the gate electrode to form an isolated gate electrode structure comprising lateral sidewalls;
forming further dopant regions for the first and the second source/drain regions in the substrate on opposed sides of the isolated gate electrode structure outside the lateral sidewalls, wherein the further dopant regions are formed of a same dopant type, the further dopant regions formed of dopants of less dopant concentration than a dopant concentration of the main dopant regions; and
forming a contact structure electrically contacting the first source/drain region, the contact structure abutting the isolated gate electrode structure in self-aligned manner.

42. The method of claim 41, wherein first and second source/drain regions are formed in a doped well in the substrate comprising dopants of a first dopant type and wherein the main dopant regions and the further dopant regions are formed of a second dopant type other than the first dopant type.

43. The method of claim 41, wherein the main dopant regions and the further dopant regions are formed by implanting dopants into the substrate, wherein the gate electrode and/or the isolated gate electrode structure serve as a mask while implanting the dopants.

44. The method of claim 43, wherein the dopants of the further dopant regions are implanted with an implantation energy higher than an implantation energy of the dopants of the main dopant regions.

45. The method of claim 44, wherein the dopants of the further dopant regions are implanted with an implantation energy of between about 5 and about 15 keV, preferably of between about 8 and 12 keV.

46. The method of claim 41, wherein the dopants of the further dopant regions are implanted with an implant dose of between about 4*10¹² and about 4*10¹⁴ atoms/cm².

47. The method of claim 41, wherein the main dopant regions are formed such that they extend closer, in lateral direction, to the channel region, compared to the further dopant regions.

48. The method of claim 41, further comprising forming shallow contact regions for the first source/drain region and the second source/drain region on opposed sides of the isolated gate electrode structure outside the lateral sidewalls.

49. The method of claim 48, wherein the shallow contact regions are implanted with a lower implant energy than the main dopant implant regions.

50. The method of claim 41, wherein the further dopant regions are implanted with an implant energy high enough to form a vertical dopant concentration profile of the first and second source/drain regions, the dopant concentration profile comprising a first range of depth in the substrate, a second derivative of the dopant concentration to the depth in the substrate being negative within the first range of depth.

51. The method of claim 41, wherein the further dopant regions are implanted to a depth in the substrate large enough to reduce leakage currents between the source/drain regions and the doped well.

52. The method of claim 41, wherein forming the gate dielectric comprises forming the gate dielectric in a recess formed in a planar surface of the substrate, the gate dielectric covering the planar substrate surface and sidewalls and a bottom surface of the recess.

53. The method of claim 52, wherein the gate electrode fills the recess and wherein the isolated gate electrode structure protrudes above the planar substrate surface.

54. A method of manufacturing an integrated semiconductor device comprising at least one transistor, the method comprising:
forming a gate dielectric over a substrate;
forming a gate electrode over the gate dielectric;
forming sidewall spacers on gate sidewalls of the gate electrode to form an isolated gate electrode structure, the sidewall spacers each comprising a lateral sidewall;
depositing a dielectric layer on the substrate and etching at least one self-aligned contact hole into the dielectric layer selectively to a respective sidewall spacer, the at least one contact hole exposing the lateral sidewall of the respective sidewall spacer and further exposing a substrate surface portion confined by the respective sidewall spacer;
implanting through the at least one contact hole a highly doped main dopant implant region and a further dopant implant region for at least one of a first source/drain diffusion region and a second source/drain diffusion region into the substrate outside the lateral sidewall of the at least one spacer exposed; and
forming at least one contact structure contacting one of the source/drain diffusion regions, the at least one contact structure abutting the lateral sidewall of the respective spacer;
wherein each further dopant implant region is formed of a same dopant type as the main dopant implant region, the further dopant implant region being formed of dopants of less dopant concentration than a dopant concentration of the main dopant implant region.

55. The method of claim 54, wherein the gate dielectric is formed on a planar surface of the substrate covering a doped well formed in the substrate.

56. The method of claim 54, wherein the gate dielectric is formed within a recess in the substrate, the gate dielectric covering a planar surface of the substrate and sidewalls and a bottom surface of the recess, the recess being formed in a doped well.

57. An integrated semiconductor device comprising at least one transistor, at least one contact structure and a substrate comprising a planar substrate surface and a doped well arranged in the substrate below the planar substrate surface, the doped well comprising dopants of a first dopant type which is one of a p-dopant type and an n-dopant type, the at least one transistor comprising:
a first and a second source/drain diffusion region arranged in the doped well and separated by a channel region;
a gate dielectric arranged on the substrate;
a gate electrode structure protruding above the planar substrate surface and above the gate dielectric, the gate electrode structure comprising a gate electrode and a gate electrode isolation comprising a spacer having a lateral sidewall;
wherein the contact structure is arranged on or above the planar substrate surface and abuts the lateral sidewall of the spacer and electrically contacts the first source/drain diffusion region,
wherein the first source/drain diffusion region comprises a highly doped main dopant implant region and a further dopant implant region both formed of dopants of a second dopant type other than the first dopant type and spatially overlapping one another;
wherein the further dopant implant region extends deeper into the substrate below the planar substrate surface than the main dopant implant region; and
wherein a lateral position of both the highly doped main dopant implant region and the further dopant implant region is defined by a self-aligned contact hole filled with the contact structure and abutting the lateral sidewall of the spacer.

58. The semiconductor device of claim 57, wherein the first source/drain diffusion region and the second source/drain diffusion region each comprises a self-aligned main dopant implant region and a self-aligned further dopant implant region, the lateral position of the main dopant implant region and the further dopant implant region both being defined by a lateral sidewall of a respective spacer.

59. The semiconductor device of claim 57, wherein the transistor forms part of a memory cell of a memory array.
